(19) United States
(12) Patent Application Publication
(10) Pub. No.: US 2010/0101729 A1
(43) Pub. Date: Apr. 29, 2010

(54) PROCESS KIT HAVING REDUCED EROSION SENSITIVITY

(75) Inventors: JONG MUN KIM, San Jose, CA (US); Xiaoye Zhao, Mountain View, CA (US); Jason Andrew Kenney, Sunnyvale, CA (US); Shahid Rauf, Pleasanton, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/259,981

(22) Filed: Oct. 28, 2008

(51) Int. Cl. H01L 21/3065

(52) U.S. Cl. 156/345.48; 156/345.51

(57) ABSTRACT

Process kits for use in a semiconductor process chambers have been provided herein. In some embodiments, a process kit for a semiconductor process chamber includes a body configured to rest about a periphery of a substrate support and having sidewalls defining an opening corresponding to a central region of the substrate support. A lip extends from the sidewalls of the body into the opening, wherein a portion of an upper surface of the lip is configured to be disposed beneath a substrate during processing. A first distance measured between opposing sidewalls of the body is greater than a width across the upper surface of a substrate to be disposed within the opening by at least about 7.87 mm.

### BACKGROUND

1. Field

Embodiments of the present invention generally relate to semiconductor process equipment, and more particularly, to process kits for a semiconductor process chamber.

2. Description of the Related Art

During semiconductor processing in a process chamber, a process kit may be disposed about a substrate and atop an exposed surface of the substrate support to protect the exposed surfaces from the processing environment, such as a plasma formed in the process chamber. As a result, the process kit may be eroded by the plasma. Unfortunately, some processes can be affected by erosion of the process kit. For example, etching processes that require the use of an electric field proximate the substrate surface may be affected by erosion of the process kit due to changes in the shape of an electric field proximate a peripheral edge of the substrate as the process kit erodes. Such changes may cause undesirable results, such as for example, increasing a tilt angle (defined as an angle from vertical of a feature etched into a substrate) in a high aspect ratio etching process. Further, such conventional process kits have short lifetimes and require frequent replacement to maintain satisfactory results of the etch process.

Accordingly, there is a need in the art for process kits having reduced erosion sensitivity and/or improved lifetimes.

### SUMMARY

A process kit for use in a semiconductor process chamber is provided herein. In some embodiments, a process kit comprises a body configured to rest about a periphery of a substrate support and having sidewalls defining an opening corresponding to a central region of the substrate support; and a lip extending from the sidewalls of the body into the opening, wherein a portion of an upper surface of the lip is configured to be disposed beneath a substrate during processing, and wherein a first distance measured between opposing sidewalls of the body is greater than a width across the upper surface of a substrate to be disposed within the opening by at least about 7.87 mm. In some embodiments, a second distance measured between the upper surface of the lip and the upper surface of the body is at least about 2.3 mm.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of an etch reactor having a process kit disposed therein in accordance with some embodiments of the present invention.

FIG. 2 depicts a partial side view of a process kit in accordance with some embodiments of the present invention.

FIG. 3 depicts a top view of a process kit in accordance with some embodiments of the present invention.

The drawings have been simplified for clarity and are not drawn to scale. To facilitate understanding, identical reference numerals have been used, wherever possible, to designate identical elements that are common to the figures. It is contemplated that some elements of one embodiment may be beneficially incorporated in other embodiments.

### DETAILED DESCRIPTION

Process kits for use in semiconductor process chambers are provide herein. Generally, the process kit advantageously may provide a more uniform electric field near the edge of the substrate during processing, thereby reducing undesired effects such as profile tilting and uniformity. The inventive process kit further may advantageously provide reduced sensitivity to erosion of the process kit, thus extending the process kit lifetime.

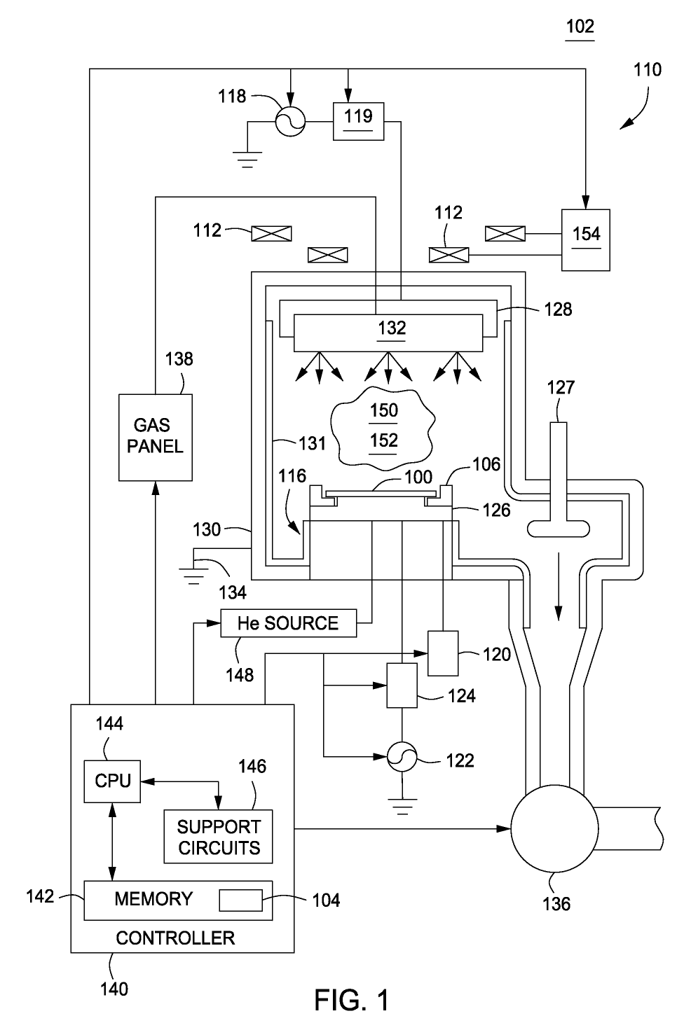

Process kits in accordance with the present invention may be configured to be disposed atop a substrate support in a process chamber. For example, FIG. 1 depicts a schematic diagram of an exemplary etch reactor 102 of the kind that may be used to practice embodiments of the invention as discussed herein. The reactor 102 may be utilized alone or, more typically, as a processing module of an integrated semiconductor substrate processing system, or cluster tool (not shown), such as a CENTURA® integrated semiconductor wafer processing system, available from Applied Materials, Inc. of Santa Clara, Calif. Examples of suitable etch reactors 102 include the DPS® line of semiconductor equipment (such as the DPS®, DPS® II, DPS® AE, DPS® G3 poly etcher, or the like), the ADVANTEDGE™ line of semiconductor equipment (such as the AdvantEdge, AdvantEdge G3), or other semiconductor equipment (such as ENABLER®, E-MAX®, or like equipment), also available from Applied Materials, Inc. The above listing of semiconductor equipment is illustrative only, and other etch reactors, and non-etch equipment (such as CVD reactors, or other semiconductor processing equipment) may be utilized with the inventive process kit as described herein.

The reactor 102 comprises a process chamber 110 having a conductive chamber wall 130 that is connected to an electrical ground 134 and at least one solenoid segment 112 positioned exterior to the chamber wall 130. The chamber wall 130 comprises a ceramic liner 131 that facilitates cleaning of the chamber 110. The byproducts and residue of the etch process are readily removed from the liner 131 after each wafer is processed. The solenoid segment(s) 112 are controlled by a DC power source 154 that is capable of producing at least 5 V. Process chamber 110 also includes a substrate support 116 that is spaced apart from a showerhead 132. The substrate support 116 comprises an electrostatic chuck 126 for retaining a substrate 100 beneath the showerhead 132. The showerhead 132 may comprise a plurality of gas distribution zones such that various gases can be supplied to the chamber 110 using a specific gas distribution gradient. The showerhead 132 is mounted to an upper electrode 128 that opposes the support pedestal 116. The electrode 128 is coupled to an RF source 118.

The electrostatic chuck 126 is controlled by a DC power supply 120 and the support pedestal 116, through a matching network 124, which is coupled to a bias source 122. Optionally, the source 122 may be a DC or pulsed DC source. The upper electrode 128 is coupled to a radio-frequency (RF) source 118 through an impedance transformer 119 (e.g., a quarter wavelength matching stub). The bias source 122 is generally capable of producing a RF signal having a tunable frequency of 50 kHz to 13.56 MHz and a power of between 0 and 5000 Watts. The source 118 is generally capable of producing a RF signal having a tunable frequency of about 160 MHz and a power between about 0 and 2000 Watts. The interior of the chamber 110 is a high vacuum vessel that is coupled through a throttle valve 127 to a vacuum pump 136. Those skilled in the art will understand that other forms of the plasma etch chamber may be used to practice the invention, including a reactive ion etch (RIE) chamber, an electron cyclotron resonance (ECR) chamber, and the like.

A process kit 106 is disposed atop the support pedestal 116 and around a substrate 100 disposed on the support pedestal 116 to protect the surfaces of the support pedestal 116 not covered by the substrate 100. The process kit 106 may be fabricated from suitable materials such as silicon (Si), silicon carbide (SiC), or the like. In some embodiments, the process kit 106 may be fabricated from silicon carbide (SiC), which may extend process kit lifetime by about 25 to about 30 percent, as compared to process kits fabricated from silicon (Si).

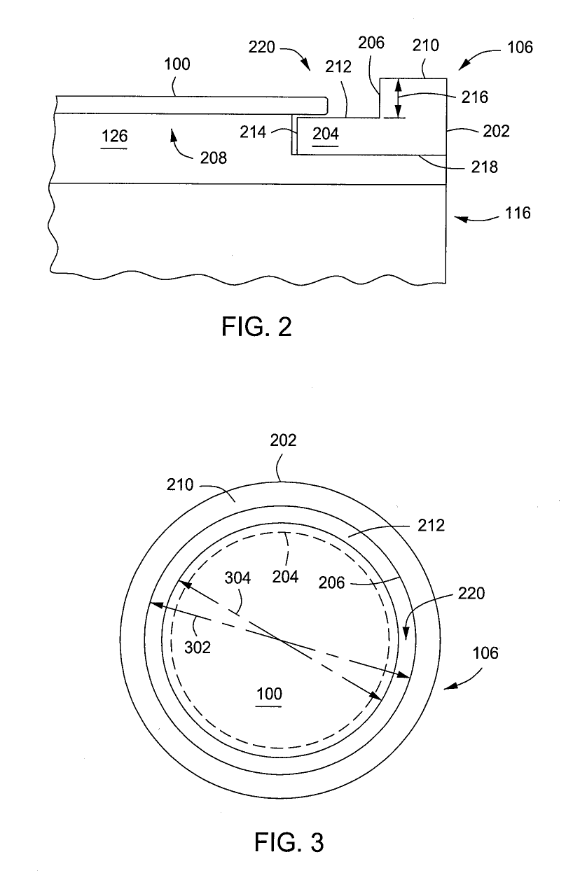

The process kit 106 is depicted in further detail in FIG. 2, which depicts a partial side view of the process kit 106 disposed atop the support pedestal 116. The process kit 106 includes a body 202 configured to rest atop the peripheral edge of the substrate support 116 (or the electrostatic chuck 126 of the substrate support 116) and having a radially inward extending lip 204 configured to be partially disposed beneath a backside of the substrate 100. The body 202 may be annular, or may be any suitable shape as dictated by the shape of the substrate support 116 (and the substrate 100 to be supported thereon). For example, the substrate 100 may be circular, such as a 200 mm or 300 mm semiconductor wafer; or alternatively, may be square such as substrates used for manufacturing solar cells or flat panel displays.

The body 202 includes a lower surface 218 and an upper surface 210, defining an overall thickness of the process kit 106. The lower surface 218 is generally configured to rest upon the opposing surface of the support pedestal 116 (or electrostatic chuck 126), and as such, may be generally planar. The upper surface 210 may be substantially parallel to an upper surface of the substrate 100, or may be disposed at an angle thereto. For example, the upper surface may be sloped, or likewise configured, to reduce contamination on the substrate during processing. For example, contamination may occur when a process material deposits on the upper surface 210 and migrates to and deposits on the substrate 100. In some embodiments, the upper surface 210 may be textured to retain process materials deposited thereon during processing.

The body 202 includes an inner sidewall 206 defining an opening 208 corresponding to a central region of the substrate support 116. In some embodiments, for example as may be configured for a 300 mm diameter substrate, the diameter of the opening 208 may be between about 297.66 to about 297.76 mm. Other diameters or dimensions may be utilized for different size and/or geometry substrates. In some embodiments, and as depicted in FIG. 2, an upper surface of the substrate support 116, such as a portion of the electrostatic chuck 126, may extend into the opening 208. Other configurations of the body 202 are possible where different substrate support and substrate configurations are utilized.

The body 202 further includes a lip 204 that extends radially inward from a lower portion of the body 202. The lip 204 is configured for being disposed beneath a peripheral edge of the substrate 100. In some embodiments, the lip 204 may extend from the sidewalls 206 of the body 202 into the opening 208. The lip 204 has an upper surface 212, where a portion of the upper surface 212 of the lip is configured for being disposed beneath a peripheral edge of the substrate 100. In some embodiments, the upper surface 212 of the lip 204 is configured to be disposed close to, but not touching, the backside of the substrate 100. In some embodiments, the upper surface 212 of the lip 204 is configured to be disposed between about 1 mil and about 5 mils (e.g., between about 0.03 and about 0.13 mm) away from the backside of the substrate 100.

In some embodiments, the lip 204 may have a width, defined between an inner edge 214 of the lip and the inner sidewall 206 of the body, of at least about 5.14 mm. Other widths may be utilized for substrates having varying dimensions. The lip 204 may extend up to about 1.27 mm beneath the edge of the substrate 100. In some embodiments, a gap may exist between the inner edge of the lip 214 and an edge of the electrostatic chuck 126, as depicted in FIG. 2. In some embodiments, the gap may be up to about 0.13 mm.

The width of the lip 204, minus the overlap with the substrate 100 defines a gap 220 between the inner sidewall 206 of the process kit and the edge of the substrate 100 (also equal to the width or diameter of the opening 208 minus the width or diameter of the substrate). The inventors have discovered that providing a larger gap between the sidewall 206 and the edge of the substrate 100 advantageously provides less change of the tilt angle over time as the process kit 106 erodes. Thus, by reducing process kit sensitivity to erosion, the process kit lifetime may be extended. Therefore, the tilt angle sensitivity may be reduced by increasing the distance between the peripheral edge of the substrate 100 and the sidewalls 206 of the body 202.

For example, a top view of the process kit 106 is depicted in FIG. 3A. The process kit 106 may be configured such that a first distance (or diameter) 302 measured between opposing portions of the sidewall 206 exceeds a width (or diameter) 304 of the substrate 100. In some embodiments, and as illustrated in FIG. 3A, the first distance 302 is equivalent to the diameter of a circle defined by the sidewalls 206 of the body 202. In some embodiments, the first distance 302 may exceed the width 304 by at least about 8 mm. In some embodiments, the first distance 302 may exceed the width 304 of the substrate 100 by between about 7.87 to about 8.13 mm. For example, as configured for a 300 mm diameter substrate, the first distance 302 may be, in some embodiments, between about 307.87 and about 308.13 mm, or about 308 mm. In some embodiments, presuming the substrate 100 is centered with respect to the process kit 106 as shown, the distance between the peripheral edge of the substrate 100 and the sidewalls 206 is at least about 3.94 mm. In some embodiments, the distance between the peripheral edge of the substrate 100 and the sidewalls 206 is at least about 4 mm.

Returning to FIG. 2, in some embodiments, the upper surface 212 of the lip 204 may be substantially parallel to the upper surface 210 of the body 202. In some embodiments, a height 216 of the sidewall 206 between the upper surface 212 of the lip 204 and the upper surface 210 of the body 202 is greater than or equal to about 2.3 mm. In some embodiments, the height 216 is between about 2.3 and about 3.0 mm, or about 2.65 mm. In some embodiments, the height 216 may be optimized to extend the lifetime of the process kit. For example, the inventors have discovered that controlling the height 216 can be utilized to control the tilt angle of resulting processing with the process kit 106. As such, the height 216 may be optimized to maximize the range of acceptable tilt angle performance. For example, in some embodiments, the process kit 106 may be configured to provide an initial tilt angle, such as an about 0.5 degree outward tilt such that erosion of the process kit 106 over time results in the tilt angle rotating through vertical and ultimately to an about 0.5 degree inward tilt. As such, the process kit 106 may be configured to have an improved lifetime. Other ranges of tilt angles may also be obtained by control over the height 216 and monitoring the quantity of erosion of the process kit 106.

In combination, both the width of the upper surface 212 and the height 216 may be optimized to both reduce tilt angle sensitivity due to process kit erosion from etching as well as optimizing the tilt angle performance of the process kit 106, thereby extending process kit lifetime.

Returning to FIG. 1, in operation, the substrate 100 is placed on the support pedestal 116 with the process kit 106 disposed thereon. The chamber interior is pumped down to a near vacuum environment, and a gas 150 (e.g., argon), when ignited produces a plasma, is provided to the process chamber 110 from a gas panel 138 via the showerhead 132. The gas 150 is ignited into a plasma 152 in the process chamber 110 by applying the power from the RF source 118 to the upper electrode 128 (anode). A magnetic field is applied to the plasma 152 via the solenoid segment(s) 112, and the support pedestal 116 is biased by applying the power from the bias source 122. During processing of the substrate 100, the pressure within the interior of the etch chamber 110 is controlled using the gas panel 138 and the throttle valve 127.

The plasma 152 may be utilized, for example, to etch a feature such as a via or trench in the substrate 100. As the substrate 100 is etched, the process kit 106 may affect the uniformity of the electric field proximate the substrate 100, thereby affecting the tilt angle of features etched in the substrate proximate the substrate edge. In addition, as the process kit 106 is etched by the plasma 152, in the process kit 106 is eroded thereby. The erosion, for example, may include reduction of the height 216, etching of the sidewalls 206, increase in the gap 220, and the like. However, the process kit 106 as discussed above, has a decreased sensitivity to erosion of the process kit 106 and the process kit lifetime may be increased.

The temperature of the chamber wall 130 is controlled using liquid-containing conduits (not shown) that are located in and around the wall. Further, the temperature of the substrate 100 is controlled by regulating the temperature of the support pedestal 116 via a cooling plate (not shown) having channels formed therein for circulating a coolant. Additionally, a back side gas (e.g., helium (He) gas) is provided from a gas source 148 into channels, which are formed by the back side of the substrate 100 and the grooves (not shown) in the surface of the electrostatic chuck 126. The helium gas is used to facilitate a heat transfer between the pedestal 116 and the substrate 100. The electrostatic chuck 126 is heated by a resistive heater (not shown) within the chuck body to a steady state temperature and the helium gas facilitates uniform heating of the substrate 100. Using thermal control of the chuck 126, the substrate 100 is maintained at a temperature of between 10 and 500 degrees Celsius.

A controller 140 may be used to facilitate control of the chamber 110 as described above. The controller 140 may be one of any form of a general purpose computer processor used in an industrial setting for controlling various chambers and sub-processors. The controller 140 comprises a central processing unit (CPU) 144, a memory 142, and support circuits 146 for the CPU 144 and coupled to the various components of the etch process chamber 110 to facilitate control of the etch process. The memory 142 is coupled to the CPU 144. The memory 142, or computer-readable medium, may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. A software routine 104, when executed by the CPU 144, causes the reactor to perform processes, such as etch processes or the like, and is generally stored in the memory 142. The software routine 104 may also be stored and/or executed by a second CPU (not shown) that is remotely located from the hardware being controlled by the CPU 144.

Thus, process kits for use in a semiconductor process chambers have been provided herein. The inventive process kit advantageously may provide a more uniform electric field near the edge of the substrate during processing, thereby reducing undesired effects such as profile tilting and uniformity. The inventive process kit further may advantageously provide reduced sensitivity to erosion of the process kit, thus extending the process kit lifetime.

While the foregoing is directed to embodiments of the present invention, other and further embodiments of the invention may be devised without departing from the basic scope thereof, and the scope thereof is determined by the claims that follow.

1. A process kit for a semiconductor process chamber, comprising:
a body configured to rest about a periphery of a substrate support and having sidewalls defining an opening corresponding to a central region of the substrate support; and
a lip extending from the sidewalls of the body into the opening, wherein a portion of an upper surface of the lip is configured to be disposed beneath a substrate during processing, and wherein a first distance measured between opposing sidewalls of the body is greater than a width across the upper surface of a substrate to be disposed within the opening by at least about 7.87 mm.

2. The process kit of claim 1, wherein a second distance measured between the upper surface of the lip and an upper surface of the body is at least about 2.3 mm.

3. The process kit of claim 1, wherein the process kit is configured to be used with a 300 mm diameter semiconductor substrate.

4. The process kit of claim 1, wherein the body and lip comprise at least one of silicon (Si) or silicon carbide (SiC).

5. The process kit of claim 1, wherein a width of the upper surface of the lip is at least about 5.14 mm.

6. The process kit of claim 5, wherein a height between the upper surface of the lip and an upper surface of the body is at least about 2.3 mm.

7. An apparatus for processing a semiconductor substrate, comprising:
a semiconductor process chamber having a substrate support disposed therein; and
a process kit disposed atop the substrate support and comprising a body disposed about a periphery of the substrate support and having sidewalls defining an opening corresponding to a central region of the substrate support, and a lip extending from the sidewalls of the body into the opening, wherein a portion of an upper surface of the lip is configured to be disposed beneath a substrate during processing, and wherein a first distance measured between opposing sidewalls of the body is greater than a width across the upper surface of a substrate to be disposed within the opening by at least about 7.87 mm.

8. The apparatus of claim 7, wherein a second distance measured between the upper surface of the lip and an upper surface of the body is at least about 2.3 mm.

9. The apparatus of claim 7, wherein the body and lip comprise at least one of silicon (Si) or silicon carbide (SiC).

10. The apparatus of claim 7, wherein the process kit is configured to be used with a 300 mm diameter semiconductor substrate.

11. (canceled)

12. The apparatus of claim 7, wherein a width of the upper surface of the lip is at least about 5.14 mm.

13. The apparatus of claim 12, wherein a height between the upper surface of the lip and an upper surface of the body is at least about 2.3 mm.

14. The apparatus of claim 7, the process chamber further comprising:
an RF power supply coupled to the process chamber and configured for providing RF power thereto.

15. The apparatus of claim 14, wherein the process kit is configured for providing a substantially uniform electric field proximate a peripheral edge of a substrate disposed thereon.

16. The apparatus of claim 14, wherein the process kit is configured for providing tilt angle sensitivity of between about −0.5 to about 0.5 degrees during formation of a feature in a substrate disposed therein.

17. The apparatus of claim 16, wherein the feature is formed proximate a peripheral edge of the substrate.

18. The apparatus of claim 16, wherein the feature may include one or more of a via or trench.

19. The process kit of claim 1, wherein the lip is configured to define a gap between the upper surface of the lip and a backside of the substrate during processing.

20. A process kit for a semiconductor process chamber, comprising:
a body configured to rest about a periphery of a substrate support configured to be used with a 300 mm diameter semiconductor substrate, the body having sidewalls defining an opening corresponding to a central region of the substrate support; and
a lip extending from the sidewalls of the body into the opening, wherein a portion of an upper surface of the lip is configured to be disposed beneath a substrate during processing, wherein a first distance measured between opposing sidewalls of the body is greater than a width across the upper surface of a substrate to be disposed within the opening by at least about 7.87 mm, and wherein a second distance measured between the upper surface of the lip and an upper surface of the body is at least about 2.3 mm.

21. The process kit of claim 20, wherein the body and lip comprise at least one of silicon (Si) or silicon carbide (SiC).
